(19) United States
(12) Patent Application Publication
(10) Pub. No.: US 2010/0261116 A1
(43) Pub. Date: Oct. 14, 2010

(54) Developer for a photopolymer protective layer

(76) Inventors: Young H. Kim, Hockessin, DE (US); John Russell Crompton, JR., Middletown, DE (US)

Correspondence Address: E I DU PONT DE NEMOURS AND COMPANY;LEGAL PATENT RECORDS CENTER, BARLEY MILL PLAZA 25/1122B, 4417 LANCASTER PIKE, WILMINGTON, DE, 19805, US

(21) Appl. No.: 11/803,451

(22) Filed: May 14, 2007

Related U.S. Application Data
(63) Continuation of application No. 11/139,458, filed on May 27, 2005, now abandoned.
(60) Provisional application No. 60/575,007, filed on May 27, 2004.

(51) Int. Cl. G03F 7/004; G03F 7/20

(52) U.S. Cl. 430/270.1; 430/331; 430/319; 977/742

(57) ABSTRACT

This invention relates to a composition used as a developer that contains a surfactant to improve the developing of photoresist, which may contain at least 50 mol % of monomers containing carboxylic acid. The present invention is also a process for the use of the composition.

This application is a continuation of, and claims the benefit of, U.S. application Ser. No. 11/139,458, filed May 27, 2005; which claimed the benefit of U.S. Provisional Application No. 60/575,007, filed on May 27, 2004; each of which is incorporated in its entirety as a part hereof for all purposes.

### FIELD OF THE INVENTION

The present invention relates to a composition and a process for its use. The composition is a developer that may be applied to a protective layer in the fabrication of electronic devices prepared from thick film pastes.

### TECHNICAL BACKGROUND

The present invention relates to a composition, and a process for its use with a protective layer in fabricating electronic devices. The composition is used as a developer.

In various electronic device fabrication processes, a substrate is coated with a conducting layer that is subsequently coated with a thick film paste. The thick film paste may contain materials such as glass frits, conductors, photo-imageable polymers and, usually, a solvent. In the fabrication of these devices, a photo-imageable protective layer may be used to isolate a photo-imageable thick film deposit from other elements of these electronic devices such as conductive layers used as electrodes.

A problem arises in some of these devices in that the solvent used in the thick film pastes, usually an ester or ether type solvent, is frequently aggressive to the polymer protective layer and may lead to short circuits. This can lead to problems on the surface of the substrate, such as peeling or dissolution of the protective layer from the substrate when that layer is exposed to the thick film paste.

One solution to this problem has previously been presented in patent application PCT/US03/36543, which discloses a system using a thick film paste prepared from a polymer based on more than 50-mole percent methacrcylic monomers. A developer often used for this kind of system is a diluted sodium carbonate or tetramethylammonium hydroxide solution.

In the present invention, the addition of a small amount of surfactant to the developer improves the developing time and cleanness of the developed image. The present invention is particularly useful for developing a protective layer prepared from a photoresist material containing a high level of carboxylic acid.

### SUMMARY OF THE INVENTION

One embodiment of the present invention is a composition that includes 0.1 to 10 percent by weight surfactant, and a developing solution selected from the group consisting of a carbonate solution, a sodium hydroxide solution, a potassium hydroxide solution and a tetramethylammonium hydroxide solution.

Another embodiment of the present invention is a process for dissolving coating material in a coating by exposing the coating to the composition described above. The coating may be in the form of a protective layer prepared from a photoresist material. The photoresist material may further be prepared from a polymer that includes at least 50 mole percent monomers having a structure selected from the group consisting of:

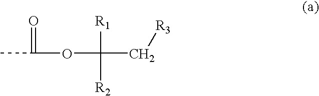

wherein R₁ is hydrogen or lower alkyl; R₂ is a lower alkyl; and R₃ is hydrogen or a lower alkyl; and wherein a lower alkyl includes alkyl groups having 1 to 6 linear or cyclic carbon atoms;

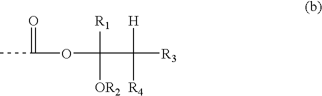

wherein R₁ is hydrogen or lower alkyl; R₂ is a lower alkyl; and R₃ and R₄ are independently hydrogen or a lower alkyl; and wherein a lower alkyl includes alkyl groups having 1 to 6 carbon atoms, and the joining of R₁ and R₂, or R₁ and either R₃ or R₄, or R₂ and either R₃ or R₄ to form a 5-, 6- or 7-membered ring; and

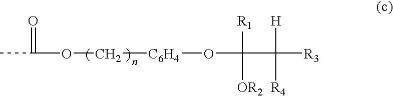

wherein R₁ is hydrogen or lower alkyl; R₂ is a lower alkyl; and R₃ and R₄ are independently hydrogen or a lower alkyl; and wherein a lower alkyl includes alkyl groups having 1 to 6 carbon atoms, and the joining of R₁ and R₂, or R₁ and either R₃ or R₄, or R₂ and either R₃ or R′₄ to form a 5-, 6- or 7-membered ring.

### DETAILED DESCRIPTION

The present invention provides a composition and a process for its use that is suitable for developing a protective layer, such as a protective layer prepared from a photoresist material containing high levels of carboxylic acid. These photoresist materials can be used in protective layers in connection with the fabrication of electronic devices where thick film paste printing technology is also used.

Suitable developers for this type of fabrication of electronic devices typically include carbonate solutions, such as a sodium carbonate solution, a sodium hydroxide solution, a potassium hydroxide solution or a tetramethylammonium hydroxide solution. A small amount of surfactant in the developer improves the developing time and cleanness of the developed image.

“Novalac-type” phenolic formaldehyde polymeric materials are typically used as photoresist materials in a protective layer in the process of fabricating electronic devices from photo-imageable thick film pastes, such as Fodel® silver paste (from DuPont, Wilmington Del.). The role of such a protective layer is to maintain spacing between the thick film deposit and other substrate structures to prevent contamination of the bottom substrate with the thick film paste. As mentioned above, in some cases, contamination of the bottom substrate may lead to short circuits. The protective layer is eventually removed by dissolution along with unimaged thick film material. However, these protective layers are frequently found to be damaged during the process of applying the paste materials on the top of the protective layer. The cause of the damage is either the dissolution of the protective layer by solvent vapors generated during the paste drying process, or plastic deformation of the photoresist material due to plastization by these vapors. Butyl carbitol, butyl carbitol acetate, dibutyl carbitol, dibutyl phthalate, texanol and terpineol are examples of the solvents currently used in thick film paste formulation.

A suitable, and often preferred, photoresist material includes a polymer in which at least 50 mole percent of the monomers in the polymer comprise a structure selected from the group consisting of:

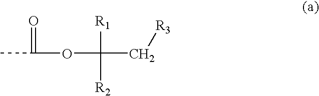

wherein R₁ is hydrogen or lower alkyl; R₂ is a lower alkyl; and R₃ is hydrogen or a lower alkyl; and wherein a lower alkyl includes alkyl groups having 1 to 6 linear or cyclic carbon atoms;

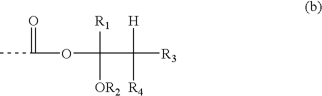

wherein R₁ is hydrogen or lower alkyl; R₂ is a lower alkyl; and R₃ and R₄ are independently hydrogen or a lower alkyl; and wherein a lower alkyl includes alkyl groups having 1 to 6 carbon atoms, and the joining of R₁ and R₂, or R₁ and either R₃ or R₄, or R₂ and either R₃ or R₄ to form a 5-, 6- or 7-membered ring; and

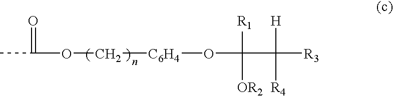

wherein R₁ is hydrogen or lower alkyl; R₂ is a lower alkyl; and R₃ and R₄ are independently hydrogen or a lower alkyl; and wherein a lower alkyl includes alkyl groups having 1 to 6 carbon atoms, and the joining of R₁ and R₂, or R₁ and either R₃ or R₄, or R₂ and either R₃ or R₄ to form a 5-, 6- or 7-membered ring.

The photoresist material typically also includes a photo-acid initiator and/or photo-acid generator. The photo-initiator may be selected from conventional photo acid generators, such as aromatic sulfonium phosphofluoride or antimony fluoride, or aromatic iodonium salt with similar anions. Other suitable photo-acid generators are described in a paper by J. V. Crivello, “The Chemistry of Photoacid Generating Compounds” in Polymeric Materials Science and Engineering, Vol. 61, American Chemical Society Meeting, Miami Fla., Sect. 11-15, 1989, pp. 62-66 and references therein. The selected photo acid generator should not undergo decomposition or dissolution during the development stage. Suitable nonionic photoacid generators include those such as PI-105 (Midori Kagaku Co., Tokyo, Japan), or high molecular weight photo acid generators such as Cyracure UVI 6976 (Dow Chemical, Midland Mich.), or CD-1012 (Aldrich Chemical, Milwaukee Wis.).

In the use of the process of this invention to fabricate an electronic device, a 0.5 to 5 micron thick coating of a photoresist material is applied to a substrate to serve as a protective layer. The photoresist material is prepared from polymers with pendant labile acid groups and photoactive reagents. Such a coating could be obtained by spin-coating or table-coating using a blade in an appropriate organic solvent. The preferred organic solvents for applying the coating are propylene glycol 1-monomethyl ether 2-acetate (PGMEA) or cyclohexanone. Next, the solvent is removed by heating the substrate to between about 70 to 100° C. for typically about 1 to 3 minutes on a hot plate.

The coating is then ready to be patterned by UV photo-irradiation through a mask. UV irradiation followed by heat treatment will cleave acid labile pendant group to convert the ester to the acid. For a higher wavelength than 248 nm, it may be desirable to include in the photoresist material a small amount (10-1000 ppm) of photosensitizer, which increases the absorption of UV light. Suitable photosensitizers may include isopropylthioxanthone (ITX), 2,4-diethyl-9H-thioxanthen-9-one (DETX), benzophenone. The UV irradiation dose is 50 to 3000 mJ/square centimeters.

Post exposure baking is then performed, the conditions for which are typically about 120 to 140° C. for about 1 to 3 minutes. This treatment results in the exposed area of the protective layer being soluble in an aqueous base developing solvent. Suitable basic developing solvents may include a carbonate solution or a low concentration sodium or potassium hydroxide solution. Preferably, a commercial aqueous base developer, such as AZ 300 from Clariant Corporation (AZ Electronic Materials, Somerville N.J.), can be used.

After development, the protective layer serves as a patterned template. As the remaining areas of the protective layer are still soluble in organic solvents, however, the compatibility of those areas with the thick film paste is limited. The protective layer can be converted to a film containing a high level of polycarboxylic acid, which is insoluble in the common organic solvents employed in thick film pastes, by exposure to UV light and subsequent heat treatment. The UV irradiation dose is typically about 50 to 3000 mJ/square centimeters. Post exposure baking conditions are typically about 120 to 140° C. for 1 to 3 minutes.

A thick film paste is then deposited on the protective layer. A preferred thick film paste is a negatively-imageable thick film paste that may be developed by an aqueous base, such as Fodel® silver paste (from DuPont, Wilmington Del.). The thick film paste may also include carbon nanotubes for field emission display applications. The thick film paste is applied on the top of the converted protective layer by such methods as screen printing so that the paste fills the vacancies in the patterned template generated in the protective layer by photo development. Subsequently, the thick film paste is photo-irradiated through a transparent substrate such as glass. The paste located in the patterned template where the protective layer is removed by photo imaging would be imaged preferentially.

As the paste is negatively developed upon irradiation, the paste becomes insoluble to developing solvents. Typically, these thick film pastes are developed by gentle spray of an aqueous base solution. The unimaged paste is washed out within a length of time that is referred to as the time-to-clear (TTC). Typically, the spray will last about 1.5 to about 3.0 times the TTC. As the irradiated protective layer is soluble in the aqueous base solution, it is removed while the unimaged thick film paste is being removed as it is spray developed.

A suitable developer for use in this process is typically a carbonate solution, such as a sodium carbonate solution, a sodium hydroxide solution, a potassium hydroxide solution or a tetramethylammonium hydroxide solution. Addition of a small amount of surfactant in the developer improves the developing time and cleanness of the developed image. In a composition of a developer and a surfactant, the surfactant is present in an amount of about 0.1 to 10 percent by weight surfactant in the weight of the total composition.

A surfactant is a molecule composed of groups of opposing solubility tendencies, i.e. one or more groups have an affinity for the phase in which the molecule or ion is dissolved, and one or more groups are antipathic to that medium. Surfactants are classified according to the charge on the surface-active moiety. In anionic surfactants, this moiety carries a negative charge; in a cationic surfactant, the charge is positive; in a nonionic surfactant, there is no charge on the molecule and the solubilizing effect may be supplied, for example, by hydroxyl groups or a long chain of ethylene oxide groups; and in an amphoteric surfactant, the solubilizing effect is provided by both positive and negative charges in the molecule. Hydrophilic, solubilizing groups for anionic surfactants include carboxylates, sulfonates, sulfates (including sulfated alcohols and sulfated alkyl phenols), phosphates (including phosphate esters), N-acylsarcosinates, and acylated protein hydrolysates. Cationics are solubilized by amine and ammonium groups. In addition to polyoxyethylene, nonionic surfactants include a carboxylic acid ester, an anhydrosorbitol ester, a glycol ester of a fatty acid, an alkyl polyglycoside, a carboxylic amide, and a fatty acid glucamide. A mixture of these surfactants is also effective.

Examples of suitable anionic surfactants include sodium dialkyl sulfosuccinate, sodium alkyl diphenyl ether disulfonate, sodium alkyl diphenyl ether disulfonate, a potassium salt of polyoxyethylene alkyl ether phosphate, sodium alkane sulfonate, or a derivative of any of the foregoing containing 2,2′,2″-nitrilotris(ethanol) as a counter cation.

Nonionic surfactants are very useful in chemical blends and mixtures because of their electrical neutrality. These surfactants offer a high degree of flexibility for preparation and structure. This is achieved by careful control of the size and ratio of the hydrophilic group verses hydrophobic group during polymerization. Recently in addition to commonly known ethoxylates, nonionic surfactants such as glycerol esters, amine oxides, acetylenic alcohol derivatives, silicones, fluorocompounds, and carbohydrate derivatives have also been found useful. A typical example of an ethoxylate surfactant is DOWFAX (Dow Chemical, Midland Mich.), which is produced by polymerizing ethylene oxide (EO), propylene oxide (P0), and/or butylene oxide (BO) in the same molecule. The ratio and order of oxide addition, together with the choice of initiator, control the chemical and physical properties. Another well-known type of nonionic surfactant is poly(oxy-1,2-ethanediyl)-alpha undecyl omega (Tomah Product Inc.).

Alternatively, a mixture of anionic and nonionic surfactants can be used. Micro-90, a mildly alkaline, aqueous solution (International Products Corp., Burlington N.J.), is particularly effective for this invention. Addition of a small amount of Micro-90 solution to various concentrations of sodium carbonate is effective in developing a polymeric protective layer that is made up of at least 50-mole percent of monomers with carboxylic groups.

The advantageous effects of this invention are demonstrated by a series of examples, as described below. The embodiments of the invention on which the examples are based are illustrative only, and do not limit the scope of the appended claims.

### Examples 1-15

The following components are dissolved to a clear solution in 895.40 grams of propylene glycol monomethyl ether acetate
491 grams of a copolymer of poly(ethoxytriethylene glycol acrylate-random-t-butyl methacrylate) [having a mole ratio of 70:30 of monomers, Mn=10,400 and a polydispersity (PD)=2.8],
105 grams Cyracure® UVI-6976 photo acid generator (Dow Chemical, Midland Mich.),
0.26 grams 1% Quanticure ITX photosensitizer in methyl ethyl ketone (Aldrich),
1.0215 grams of 2,3-diazabicyclo[3.2.2]non-2-ene, 1,4,4-trimethyl-,2,3-dioxide (Hampford Research, Inc., Stratford Conn.),
7.364 grams of Triton® X 100 non-ionic surfactant, and
0.43 grams of 2-(2-hydroxy-5-methyl phenyl)benzo-triazole.

Using a 2 mil doctor blade, the solution is cast on a glass plate and allowed to air dry for 10 minutes. The film is then dried for 2 min at 70° C. on a hot plate. The film is exposed to about a 2.25 J/cm² broad band UV light using a 20 micron photomask, then heat treated on a hot plate at 120° C. for 2 min. The imaged part is developed by spraying, for the time as shown in Table 1, a developing solution containing the carbonate and Micro 90 components as also shown in Table 1. The film is then washed with deionized water for 1 min., then dried on a hot plate at 90° C. for 30 sec. The remaining film is flood exposed about a 1.5 J/cm² UV light then heat-treated at 120° C. for 2 mins. The remaining film could be washed out with the same developer as shown in Table 1.

TABLE 1

| | | Micro-90 | | |
|---|---|---|---|---|
| | Carbonate | Surfactant | | |
| | Concentration | Solution | Time | |
| | wt % | vol. % | in minutes | results |
| Example 1 | 0.25 | 3 | 1 | nearly no residue |
| Example 2 | 0.75 | 3 | 1 | some residue |
| Example 3 | 0.5 | 3 | 2 | nearly no residue |
| Example 4 | 0.5 | 1 | 3 | no residue |
| Example 5 | 0.75 | 3 | 3 | nearly no residue |
| Example 6 | 0.5 | 3 | 2 | no residue |
| Example 7 | 0.75 | 1 | 2 | residue |
| Example 8 | 0.5 | 1 | 1 | no residue |
| Example 9 | 0.25 | 3 | 3 | nearly no residue |
| Example 10 | 0.5 | 5 | 1 | no residue |
| Example 11 | 0.5 | 5 | 3 | no residue |
| Example 12 | 0.25 | 1 | 2 | no residue |
| Example 13 | 0.25 | 5 | 2 | nearly no residue |
| Example 14 | 0.75 | 5 | 2 | no residue |
| Example 15 | 0.5 | 3 | 2 | no residue |

What is claimed is:

1. A composition comprising 0.1 to 10 percent by weight polyether surfactant, and a developing solution selected from the group consisting of a carbonate solution, a sodium hydroxide solution, a potassium hydroxide solution, and a tetramethylammonium hydroxide solution.

2. The composition of claim 1 wherein the developing solution comprises a carbonate solution.

3. The composition of claim 1 wherein the developing solution comprises a sodium hydroxide solution.

4. The composition of claim 1 wherein the developing solution comprises a potassium hydroxide solution.

5. The composition of claim 1 wherein the developing solution comprises a tetramethylammonium hydroxide solution.

6. The composition of claim 1 wherein the polyether surfactant comprises polymerized ethylene oxide moieties.

7. A process for dissolving coating material in a coating comprising exposing the coating to the composition of claim 1.

8. The process of claim 7 wherein the coating comprises a protective layer in an electronic device.

9. The process of claim 7 wherein the coating comprises a photoresist material.

10. The process of claim 9 wherein the photoresist material comprises a polymer at least 50 mole percent of which comprises monomeric units having a structure selected from one or more of the members of the group consisting of (a), (b) and (c) as follows: 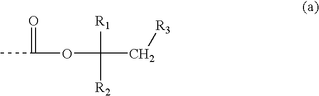
wherein R₁ is hydrogen or lower alkyl; R₂ is a lower alkyl; and R₃ is hydrogen or a lower alkyl; and
wherein a lower alkyl includes alkyl groups having 1 to 6 linear or cyclic carbon atoms; 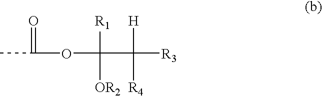
wherein R₁ is hydrogen or lower alkyl; R₂ is a lower alkyl; and R₃ and R₄ are independently hydrogen or a lower alkyl; and wherein a lower alkyl includes alkyl groups having 1 to 6 carbon atoms and the joining of R₁ and R₂, or R₁ and either R₃ or R₄, or R₂ and either R₃ or R₄ to form a 5-, 6- or 7-membered ring; and 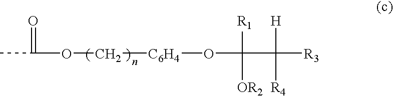
wherein R₁ is hydrogen or lower alkyl; R₂ is a lower alkyl; and R₃ and R₄ are independently hydrogen or a lower alkyl; wherein a lower alkyl includes alkyl groups having 1 to 6 carbon atoms and the joining of R₁ and R₂, or R₁ and either R₃ or R₄, or R₂ and either R₃ or R₄ to form a 5-, 6- or 7-membered ring.

11. A process for fabricating an electronic device that comprises a substrate, comprising:
(a) forming a protective layer on a first side of the substrate from a composition that comprises a polymer at least 50 mole percent of which comprises monomeric units having a structure selected from one or more of the members of the group consisting of (i), (ii) and (iii) as follows: 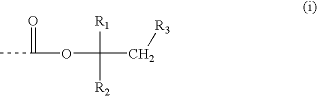
wherein R₁ is hydrogen or lower alkyl; R₂ is a lower alkyl; and R₃ is hydrogen or a lower alkyl; and
wherein a lower alkyl includes alkyl groups having 1 to 6 linear or cyclic carbon atoms; 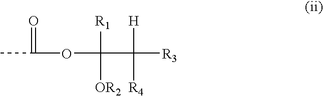
wherein R₁ is hydrogen or lower alkyl; R₂ is a lower alkyl; and R₃ and R₄ are independently hydrogen or a lower alkyl; and wherein a lower alkyl includes alkyl groups having 1 to 6 carbon atoms and the joining of R₁ and R₂, or R₁ and either R₃ or R₄, or R₂ and either R₃ or R₄ to form a 5-, 6- or 7-membered ring; and 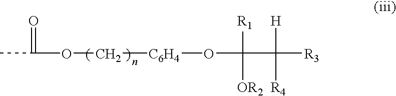
wherein R₁ is hydrogen or lower alkyl; R₂ is a lower alkyl; and R₃ and R₄ are independently hydrogen or a lower alkyl; wherein a lower alkyl includes alkyl groups having 1 to 6 carbon atoms and the joining of R₁ and R₂, or R₁ and either R₃ or R₄, or R₂ and either R₃ or R₄ to form a 5-, 6- or 7-membered ring;
(b) irradiating the protective layer through a mask;
(c) heating the device;
(d) contacting the protective layer with a developing solution to remove the portions of the protective layer composition exposed to radiation in step (b), and thereby form a patterned protective layer;
(e) irradiating the patterned protective layer;
(f) heating the device;
(g) applying to the patterned protective layer a paste composition;
(h) irradiating the device from a second side of the substrate to form a pattern in the paste composition; and
(i) contacting the paste composition and the patterned protective layer with a developing solution to remove (I) the portions of the paste composition not exposed to radiation in step (h), and (II) the patterned protective layer;
wherein the developing solution in one or both of steps (d) and (i) comprises a composition according to claim 1.

12. The process of claim 11 wherein the developing solution in step (d) comprises a composition according to claim 1.

13. The process of claim 11 wherein the developing solution in step (i) comprises a composition according to claim 1.

14. The process of claim 11 wherein the developing solution in both steps (d) and (i) comprises a composition according to claim 1.

15. The process of claim 11 wherein the thick film paste composition comprises silver.

16. The process of claim 11 wherein the thick film paste composition comprises carbon nanotubes.

17. The process of claim 11 wherein the thick film paste composition comprises both silver and carbon nanotubes.
